(19) United States
(12) Patent Application Publication
(10) Pub. No.: US 2009/0046510 A1
(43) Pub. Date: Feb. 19, 2009

(54) Apparatus and method for multi-bit programming

(75) Inventors: Seung-Hwan Song, Seo-gu (KR); Jun Jin Kong, Yongin-si (KR); Sung Chung Park, Yuseong-gu (KR); Heeseok Eun, Seoul (KR); Dong Hyuk Chae, Seoul (KR); Kyoung Lae Cho, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/007,775

(22) Filed: Jan. 15, 2008

(30) Foreign Application Priority Data
Aug. 14, 2007 (KR) 10-2007-0081886

(51) Int. Cl. G11C 7/10

(52) U.S. Cl. 365/185.03

(57) ABSTRACT

Multi-bit programming apparatuses and methods are provided. A multi-bit programming apparatus may include: a first programming unit that stores data corresponding to a number of first bits in at least one first memory cell that may be connected to at least one first bit line; and a second programming unit that stores data corresponding to a number of second bits in at least one second memory cell that may be connected to at least one second bit line. Through this, it may be possible to improve data reliability and increase a number of bits to be stored in the entire memory cell.

### PRIORITY STATEMENT

This application claims priority under 35 U.S.C. § 119 to Korean Patent Application No. 10-2007-0081886, filed on Aug. 14, 2007, in the Korean Intellectual Property Office (KIPO), the entire contents of which are incorporated herein by reference.

### BACKGROUND

1. Field

Example embodiments relate to apparatuses and/or methods that may program data in memory devices. Also, example embodiments relate to multi-bit (multi-level) programming apparatuses and/or methods that may program data in multi-level memory devices.

2. Description of Related Art

A single-level cell (SLC) memory device may store one bit of data in a single memory cell. The SLC memory may be referred to as a single-bit cell (SBC) memory. The SLC memory may store and read data of one bit at a voltage level included in two distributions that may be divided by a threshold voltage level programmed in a memory cell. For example, when a voltage level read from the memory cell is greater than 0.5V and less than 1.5V, it may be determined that the data stored in the memory cell has a logic value of “1”. When the voltage level read from the memory cell is greater than 2.5V and less than 3.5V, it may be determined that the data stored in the memory cell has a logic value of “0”. The data stored in the memory cell may be classified depending on the difference between cell currents and/or cell voltages during the reading operations.

Meanwhile, a multi-level cell (MLC) memory device that can store data of two or more bits in a single memory cell has been proposed in response to a need for higher integration of memory. The MLC memory device may also be referred to as a multi-bit cell (MBC) memory. However, as the number of bits stored in the single memory cell increases, reliability may deteriorate and the read-failure rate may increase. To store ‘m’ bits in a single memory cell, 2^{m} voltage level distributions may be required. But, since the voltage window for a memory cell may be limited, the difference in threshold voltage between adjacent bits may decrease as ‘m’ increases, which may cause the read-failure rate to increase. For this reason, it may be difficult to improve storage density using a MLC memory device.

### SUMMARY

Example embodiments may provide apparatuses and/or methods that may apply a new multi-level (multi-bit) programming scheme in a multi-level cell (MLC) memory device and thereby reduce an error when reading data from the MLC memory device.

Example embodiments may also provide apparatuses and/or methods that may apply a new multi-level (multi-bit) programming scheme in an MLC memory device and thereby improve data reliability and increase a number of bits to be stored in the entire memory cell.

Example embodiments may also provide apparatuses and/or methods that may apply a multi-level (multi-bit) programming scheme in a MLC memory device and thereby stably increase a number of bits to be stored in the entire memory cell array.

According to example embodiments, a multi-bit programming apparatus may include: a first programming unit that may store data corresponding to a number of first bits in at least one first memory cell that may be connected to at least one first bit line; and a second programming unit that may store data corresponding to a number of second bits in at least one second memory cell that may be connected to at least one second bit line.

According to example embodiments, a multi-bit programming method may include: storing data corresponding to a number of first bits in at least one first memory cell that may be connected to at least one first bit line; and storing data corresponding to a number of second bits in at least one second memory cell that may be connected to at least one second bit line.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 illustrates a multi-bit programming apparatus according to example embodiments;

FIG. 2 is a block diagram illustrating a programming control unit of FIG. 1;

FIG. 3 illustrates a multi-bit programming apparatus according to example embodiments;

FIG. 4 is a graph illustrating a distribution of threshold voltages of memory cells programmed by a multi-programming apparatus according to example embodiments;

FIG. 5 illustrates a process of storing, by a multi-bit programming apparatus, data in a memory cell array according to example embodiments;

FIG. 6 illustrates another process of storing, by a multi-bit programming apparatus, data in a memory cell array according to example embodiments;

FIG. 7 illustrates another process of storing, by a multi-bit programming apparatus, data in a memory cell array according to example embodiments;

FIG. 8 illustrates a part of the memory cell array of FIG. 7;

FIG. 9 is a flowchart illustrating a multi-bit programming method according to example embodiments;

FIG. 10 is a flowchart illustrating another multi-bit programming method according to example embodiments; and

FIG. 11 is a flowchart illustrating another multi-bit programming method according to example embodiments.

### DETAILED DESCRIPTION OF EXAMPLE EMBODIMENTS

Detailed example embodiments are disclosed herein. However, specific structural and functional details disclosed herein are merely representative for purposes of describing example embodiments. Example embodiments may, however, may be embodied in many alternate forms and should not be construed as being limited to only the embodiments set forth herein.

Accordingly, while example embodiments are capable of various modifications and alternate forms, embodiments thereof are shown by way of example in the drawings and will herein be described in detail. It should be understood, however, that there is not intent to limit example embodiments to the particular forms disclosed, but to the contrary, example embodiments are to cover all modifications, equivalents, and alternatives falling within the scope of the example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

Reference will now be made to example embodiments, which are illustrated in the accompanying drawings, wherein like reference numerals may refer to like components throughout.

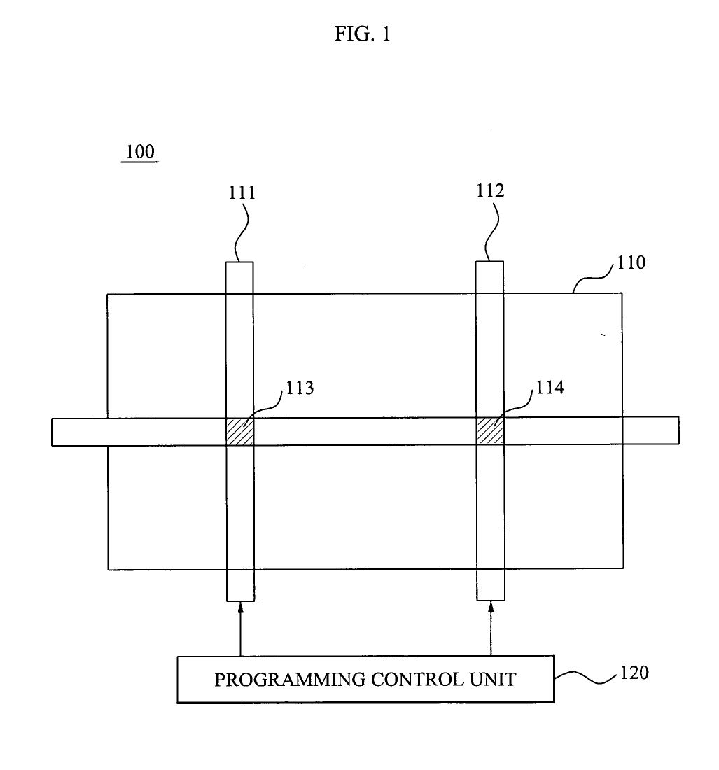

FIG. 1 illustrates a multi-bit programming apparatus 100 according to an example embodiment.

Referring to FIG. 1, the multi-bit programming apparatus 100 may include a memory cell array 110 and a programming control unit 120.

The programming control unit 120 may store data corresponding to a number of first bits in a first memory cell 113 that may be connected to a first bit line 111, and may store data corresponding to a number of second bits in a second memory cell 114 that may be connected to a second bit line 112.

The number of first bits may indicate the density of data stored in the first memory cell 113. For example, when the number of first bits is four, four-bit data may be stored in the first memory cell 113.

Similarly, the number of second bits may indicate the density of data stored in the second memory cell 114.

The programming control unit 120 may store data corresponding to the number of first bits in the first memory cell 113 by changing a threshold voltage of the first memory 113. In example embodiments, the changed threshold voltage of the first memory cell 113 may be any one of voltage levels corresponding to the number of first bits.

For example, if the number of first bits is 4, the changed threshold voltage of the first memory cell 113 may be any one of 16 (=2⁴) voltage levels. Four-bit data stored in the first memory cell 113 may be associated with a voltage level of the changed threshold voltage of the first memory cell 113.

The programming control unit 120 may store data corresponding to the number of second bits in the second memory cell 114 by changing a threshold voltage of the second memory cell 114. In example embodiments, the changed threshold voltage of the second memory cell 114 may be any one of voltage levels corresponding to the number of second bits.

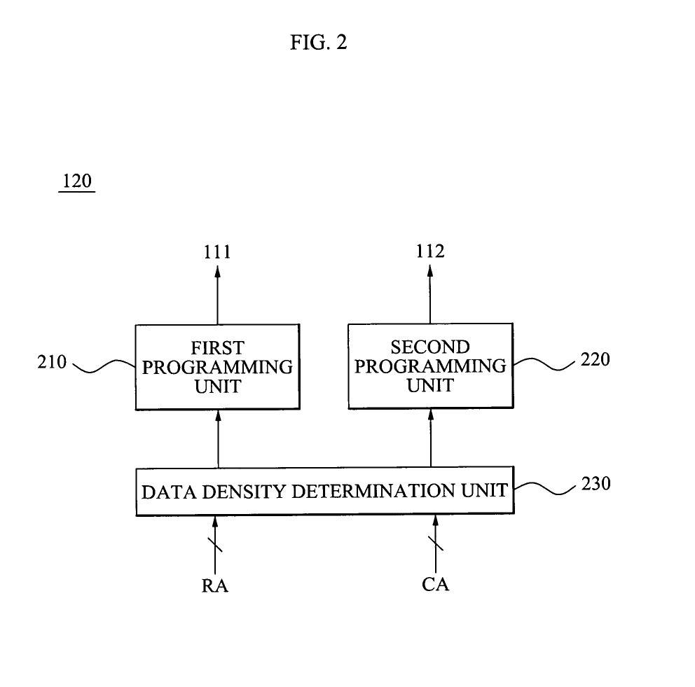

FIG. 2 is a block diagram illustrating the programming control unit 120 of FIG. 1.

Referring to FIG. 2, the programming control unit 120 may include a first programming unit 210, a second programming unit 220, and a data density determination unit 230.

The first programming unit 210 may store data corresponding to a number of first bits in the first memory cell 113 which may be connected to the first bit line 111.

The first programming unit 210 may store data corresponding to the number of first bits in the first memory cell 113 by changing a threshold voltage of the first memory cell 113 which may be connected to the first bit line 111.

The second programming unit 220 may store data corresponding to a number of second bits in the second memory cell 114 which may be connected to the second bit line 112.

The second programming unit 220 may store data corresponding to the number of second bits in the second memory cell 114 by changing a threshold voltage of the second memory cell 114 which may be connected to the second bit line 112.

The data density determination unit 230 may determine the number of first bits and the number of second bits for each word line based on a bit line location.

According to example embodiments, the data density determination unit 230 may determine the number of first bits to be different from the number of second bits, and thereby make the density of the data stored in the first memory cell 113 different from the density of the data stored in the second memory cell 114.

The data density determination 230 may receive a row address (RA) that is a word line selection address and a column address (CA) that is a bit line selection address, and determine the density of data to be stored in a memory cell represented by the RA and the CA.

According to example embodiments, a standard to determine the number of first bits and the number of second bits of the data density determination unit 230 may be pre-determined by the structure of the memory cell array 110 and stored in the data density determination unit 230.

The number of first bits may be pre-determined by a location of the first memory cell 113 in the memory cell array 110. The number of second bits may be pre-determined by a location of the second memory cell 114 in the memory cell array 110.

According to example embodiments, the first programming unit 210 may simultaneously perform multi-bit programming with respect to memory cells that are allocated with the same number of first bits by the data density determination unit 230.

According to example embodiments, the second programming unit 220 may simultaneously perform multi-bit programming with respect to memory cells that are allocated with the same number of second bits by the data density determination unit 230.

According to example embodiments, if the number of first bits is two and the number of second bits is four, the first programming unit 210 may simultaneously perform multi-bit programming with respect to memory cells of which the data density is determined as two bits. The second programming unit 220 may simultaneously perform multi-bit programming with respect to memory cells of which the data density is determined as four bits.

In example embodiments, the first programming unit 210 may simultaneously perform multi-bit programming with respect to memory cells that are connected to the same word line. Similarly, the second programming unit 220 may simultaneously perform multi-bit programming with respect to memory cells that are connected to the same word line.

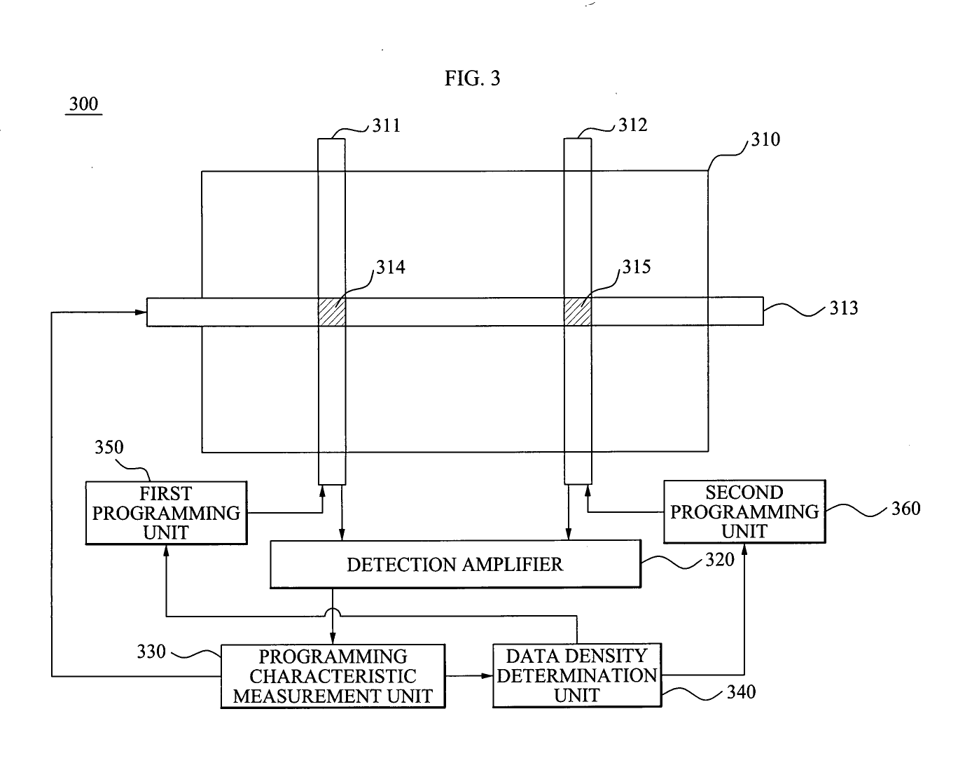

FIG. 3 illustrates a multi-bit programming apparatus 300 according to an example embodiment.

Referring to FIG. 3, the multi-bit programming apparatus 300 may include a programming characteristic measurement unit 330, a data density determination unit 340, a first programming unit 350, and a second programming unit 360.

The programming characteristic measurement unit 330 may measure programming characteristics of a first memory cell 314 and a second memory cell 315 of a memory cell array 310.

The data density measurement unit 340 may determine a number of first bits of the first memory cell 314 and a number of second bits of the second memory cell 315 based on the measured programming characteristics.

The first memory cell 314 and the second memory cell 315 may be memory cells that are included in the memory cell array 310 and connected to the same word line 313.

The first programming unit 350 may store data corresponding to the number of first bits in the first memory cell 314. The second programming unit 360 may store data corresponding to the number of second bits in the second memory cell 315.

In example embodiments, the programming characteristics measured by the programming characteristic measurement unit 330 may be a tendency for a threshold voltage of each of the first memory cell 314 and the second memory cell 315 to change.

A process of measuring the programming characteristic (tendency for the threshold voltage to change) of the first memory cell 314 by the programming characteristic measurement unit 330 is described below.

The programming characteristic measurement unit 330 may apply a word line control voltage to the word line 313. The programming characteristic measurement unit 330 may determine whether the threshold voltage of the first memory cell 314 is greater than or less than the word line control voltage based on a signal level that is detected through the first bit line 311 and a detection amplifier 320.

The programming characteristic measurement unit 330 may detect a change in the signal level that is detected through the detection amplifier 320, and measure the threshold voltage of the first memory cell 314, while changing the word line control voltage applied to the word line 313.

If a voltage condition to program the first memory cell 314 is maintained for a predetermined period of time, the threshold voltage of the first memory cell 314 may be changed. The programming characteristic measurement unit 330 may compare threshold voltages of the first memory cell 314 before and after the change, and measure a changing tendency in the threshold voltage of the first memory cell 314.

The measuring process of the programming characteristic may be applied to both the first memory cell 314 and the second memory cell 315.

The programming characteristic measurement unit 330 may apply a word line control voltage to the word line 313. The programming characteristic measurement unit 330 may determine whether the threshold voltage of the second memory cell 315 is greater than or not greater than the word line control voltage based on a signal level that is detected through the second bit line 312 and the detection amplifier 320.

The measuring process of the programming characteristic may be used to detect whether or not the first memory cell 314 and the second memory cell 315 are functioning properly.

For example, if the measured programming characteristic (tendency for the threshold voltage to change) of the first memory cell 314 is outside an allowable range, the programming characteristic measurement unit 330 may determine the first memory cell 314 is not functioning properly.

In example embodiments, the allowable range of the programming characteristic may be a numerical range based on statistical probability from the average of threshold voltages that change when a normal memory cell is programmed.

The data density determination unit 340 may determine the number of first bits and the number of second bits based on the measured programming characteristic.

A first programming unit of a multi-bit programming apparatus according to example embodiments may store data corresponding to a number of first bits in at least one first memory cell which may be connected to at least one first bit line.

A second programming unit of the multi-bit programming apparatus may store data corresponding to a number of second bits in at least one second memory cell which may be connected to at least one second bit line.

A non-volatile memory generally requires a relatively long programming time and thus programming may be simultaneously performed with respect to a plurality of memory cells. The simultaneously programmed plurality of memory cells may be a part of memory cells that are each connected to the same word line. Memory cells connected to the same word line may be referred to as a page.

When data is stored in an initially programmed page among a plurality of pages connected to the same word line, and the data is transformed due to an effect of a programming process to another page, it may be referred to as program disturbance.

When a first page connected to one word line is initially programmed, the average of threshold voltages of memory cells of the first page may be changed to V1.

The first page and a second page may be connected to the same word line.

When the first page is programmed and then the second page is programmed, the average of threshold voltages of memory cells of the second page may be changed to V2.

When the programming process is consistently controlled, V1 and V2 may be substantially identical to each other.

While the second page is being programmed, memory cells of the first page may receive a high voltage stress through the word line. Accordingly, due to effect of the high voltage stress, the average of threshold voltages of the memory cells of the first page may not be maintained at V1.

Although the programming process is consistently controlled, it may be difficult to make the average of threshold voltages of the memory cells of the first page the same as the average of threshold voltages of the memory cells of the second page. Generally, it may be more difficult to control the average of threshold voltages of memory cells of a page that is initially programmed and thus exposed to the high voltage stress for a relatively longer time.

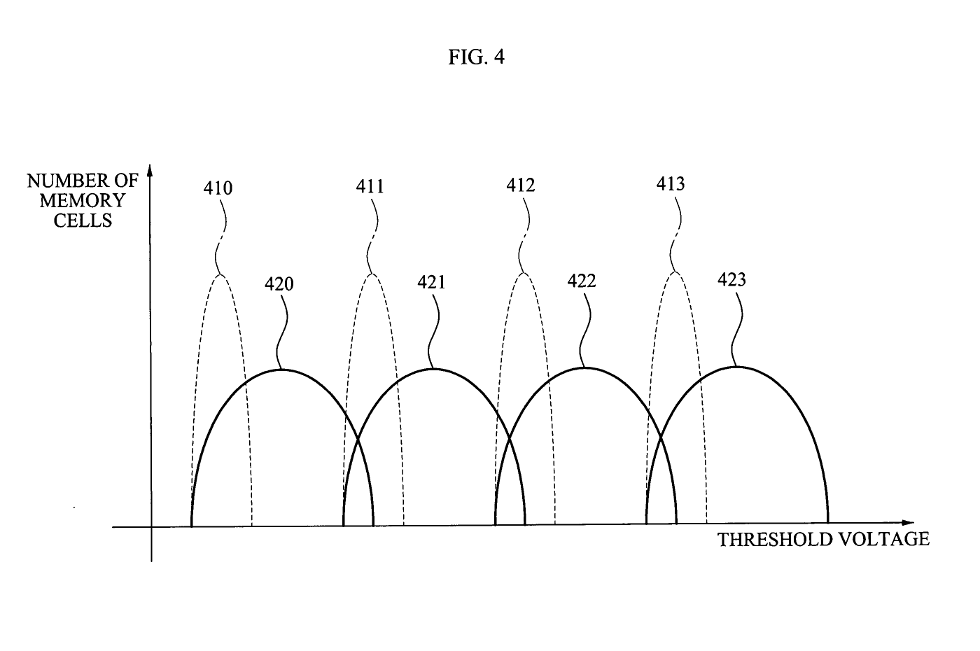

FIG. 4 is a graph illustrating a distribution of threshold voltages of memory cells programmed by a multi-programming apparatus according to an example embodiment.

Referring to FIG. 4, in a state where only a first page is programmed, threshold voltages of unprogrammed memory cells corresponding to an unprogrammed state “00” may comply with a distribution 410.

In FIG. 4, a two-bit programming process may be assumed. In a state where only the first page is programmed, threshold voltages of programmed memory cells of the first page corresponding to a state “01” may comply with a distribution 411.

Similarly, in a state where only the first page is programmed, threshold voltages of programmed memory cells of the first page corresponding to a state “10” may comply with a distribution 412.

In a state where only the first page is programmed, threshold voltages of programmed memory cells of the first page corresponding to a state “11” may comply with a distribution 413.

The distributions 410 through 413 may be distinctively divided without overlapping.

When a certain level of voltage is applied to a gate of memory cells through the word line, it may be possible to detect current flowing in the memory cells, and determine whether the threshold voltages of the memory cells are less than a voltage applied to the word line based on the detected magnitude of current.

When a voltage between the distributions 411 and 412 is applied to the word line, it may be possible to detect current flowing in the memory cells, and identify memory cells corresponding to “00” and “01” and memory cells corresponding to “10” and “11”, based on the detected magnitude of current.

When a voltage between the distributions 410 and 411 is applied to the word line, it may be possible to detect current flowing in the memory cells, and identify memory cells corresponding to “00” based on the detected magnitude of current.

When a voltage between the distributions 412 and 413 is applied to the word line, it may be possible to detect current flowing in the memory cells, and identify memory cells corresponding to “11” based on the detected magnitude of current.

After the second page is programmed, the threshold voltages of the memory cells of the first page may comply with distributions 420, 421, 422, and 423.

While the second page is being programmed, the memory cells of the first page may receive the high voltage stress through the word line. Accordingly, threshold voltages of the memory cells of the first memory may increase to be over an original value and the increase may be different for each memory cell. As described above, this may be referred to as program disturbance.

After the second program is programmed, threshold voltages of memory cells of the first page corresponding to “00” may comply with the distribution 420.

After the second program is programmed, threshold voltages of memory cells corresponding to “01” may comply with the distribution 421.

After the second program is programmed, threshold voltages of memory cells corresponding to “10” may comply with the distribution 422.

After the second program is programmed, threshold voltages of memory cells corresponding to “11” may comply with the distribution 423.

The memory cells of the distribution 420 may be partially overlapped with the memory cells of the distribution 421. Although a certain level of voltage may be applied to memory cells of the word line, and the threshold voltages of the memory cells may be read based on the magnitude of current flowing in the memory cells, the memory cells of the distributions 420 and 421 may be indistinctively divided.

As described above, the two-bit programming process may not be applied to the memory cells whose threshold voltages are changed due to the high voltage stress since post-programmed data may not be accurately read. Accordingly, either single-bit or 1.5-bit programming process may be applied to memory cells whose threshold voltages will be definitely changed.

A data density determination unit of a multi-bit programming apparatus according to example embodiments may determine whether to apply either a single-bit program process or a multi-bit programming process based on programming characteristics of memory cells, particularly, the changing tendency of threshold voltages.

According to example embodiments, the data density determination unit may determine whether to apply either an m-bit programming process or an n-bit programming process based on the changing tendency of threshold voltages. Here, n<m.

In example embodiments, a multi-bit programming apparatus may store data density, for example, whether a memory cell can store two bits or four bits, in a database. The data density may be determined with respect to each of memory cells.

The database may be configured using some cells of a page of a memory cell array.

According to example embodiments, when the changing tendency in a threshold voltage of a memory cell is far outside an allowable range, the multi-bit programming apparatus may determine the memory cell is functioning improperly and make programming access, read access, or both, unavailable for the determined memory cell.

In example embodiments, the multi-bit programming apparatus may store an error determination for each of memory cells in a database.

In example embodiments, the database may be configured using some cells of a page of a memory cell array.

In addition to the program disturbance, the following may be causes of diversity of the changing tendency in a threshold voltage of each of memory cells.

As the size of semiconductors is being slimmed down and the width of electrical wiring generated by metal and/or poly-silicon may be narrowed due to development in semiconductor manufacturing technologies, electrical resistance of the word line may not be neglected. Moreover, as more memory cells may be connected to one word line to increase the integration of memory cells, the parasitic capacitance of the word line may not be neglected.

As the electrical resistance and the parasitic capacitance of the word line may increase, a distribution chart of programming characteristics, particularly, changing tendency in a threshold voltage, of memory cells connected to the same word line may be spread. The distribution of post-programmed threshold voltages may be spread, instead of concentrating on the average and thus the data storage density of the memory cells may not be set as the same.

Multi-bit programming apparatuses and/or methods according to example embodiments may set the data storage density of memory cells to be different from each other, and thereby optimize the data storage density of the entire memory cell array within a range in which the accuracy and stability may be obtained in storing and reading the data.

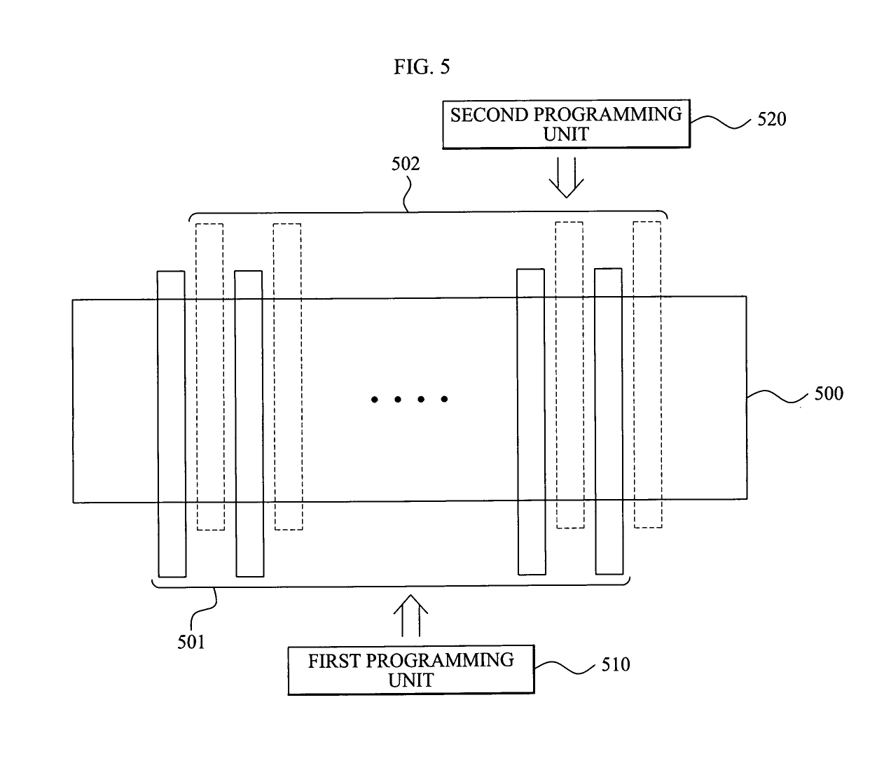

FIG. 5 illustrates a process of storing, by a multi-bit programming apparatus, data in a memory cell array 500 according to an example embodiment.

Referring to FIG. 5, a first programming unit 510 of the multi-bit programming apparatus may store data corresponding to a number of first bits in memory cells that are connected to even bit lines 501 of the memory cell array 500.

A second programming unit 520 of the multi-bit programming apparatus may store data corresponding to a number of second bits in memory cells that are connected to odd bit lines 502 of the memory cell array 500.

After the first programming unit 510 stores the data corresponding to the number of first bits in the memory cells connected to the even bit lines 501, the second programming unit 520 may store the data corresponding to the number of second bits in the memory cells connected to the odd bit lines 502.

As described above, due to the program disturbance, threshold voltages of the memory cells connected to the even bit lines 501 may change during a data storage process of the second programming unit 520.

It may be highly possible that the threshold voltages of the memory cells connected to the even bit lines 501 may be distributed in a relatively wider range. Accordingly, the multi-bit programming apparatus may set the number of first bits to be less than or greater than the number of second bits.

For example, when the number of first bits is two and the number of second bits is four, the multi-bit programming apparatus may store two-bit data in each of the memory cells connected to the even bit lines 501, and store four-bit data in each of the memory cells connected to the odd bit lines 502.

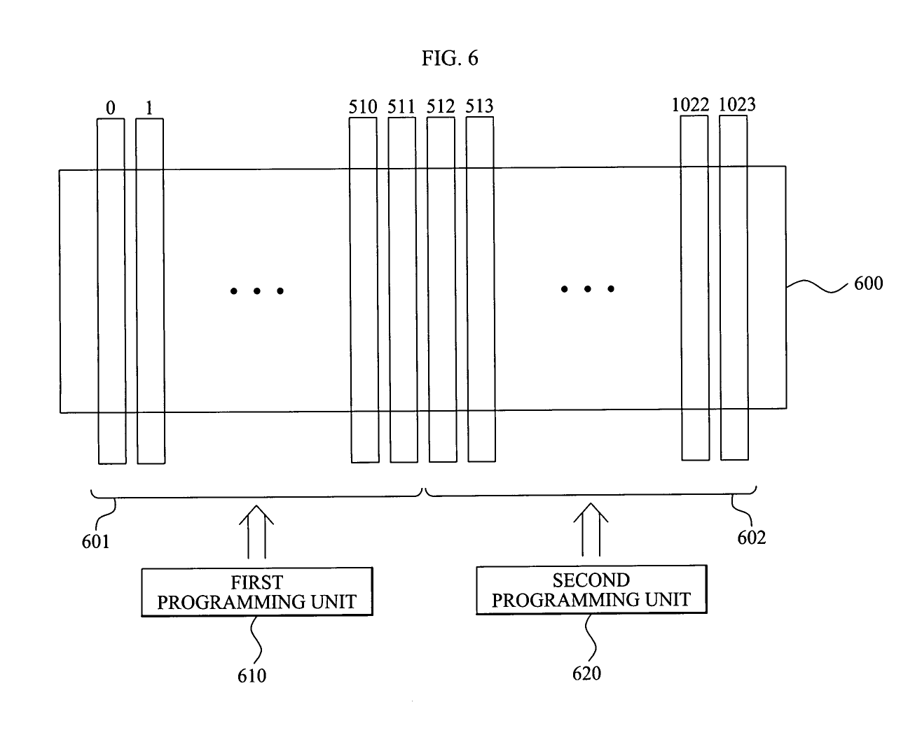

FIG. 6 illustrates a process of storing, by a multi-bit programming apparatus, data in a memory cell array 600 according to another example embodiment.

Referring to FIG. 6, a first programming unit 610 of the multi-bit programming apparatus may store data corresponding to a number of first bits in memory cells which may be connected to bit lines 601 corresponding to a low address.

A second programming unit 620 of the multi-bit programming apparatus may store data corresponding to a number of second bits in memory cells that are connected to bit lines 602 corresponding to a high address.

Bit lines 601 may include bit lines 0, 1, 510, 511, etc. and bit lines 602 may include bit lines 512, 513, 1022, 1023, etc.

After the first programming unit 610 stores the data corresponding to the number of first bits in the memory cells connected to the bit lines 601 corresponding to the low address, the second programming unit 620 may store the data corresponding to the number of second bits in the memory cells connected to the bit lines 602 corresponding to the high address.

As described above, due to the program disturbance, threshold voltages of the memory cells connected to the bit lines 601 corresponding to the low address may change during a data storage process of the second programming unit 620.

It may be highly possible that the threshold voltages of the memory cells connected to the bit lines 601 corresponding to the low address may be distributed in a relatively wider range. Accordingly, the multi-bit programming apparatus may set the number of first bits to be less than or greater than the number of second bits.

For example, when the number of first bits is two and the number of second bits is four, the multi-bit programming apparatus may store two-bit data in each of the memory cells connected to the bit lines 601 corresponding to the low address, and store four-bit data in each of the memory cells connected to the bit lines 602 corresponding to the high address.

According to example embodiments, the data storage process of the first programming unit 610 and the second programming unit 620 may be simultaneously performed.

In example embodiments, if driving circuitry for driving the word line is located adjacent to the bit lines 601 corresponding to the low address, the threshold voltages of the memory cells connected to the bit lines 602 corresponding to the high address may be ineffectively controlled.

In this case, the multi-bit programming apparatus may set the number of first bits to be less than the number of second bits and store more data in the memory cells connected to the bit lines 601 corresponding to the low address.

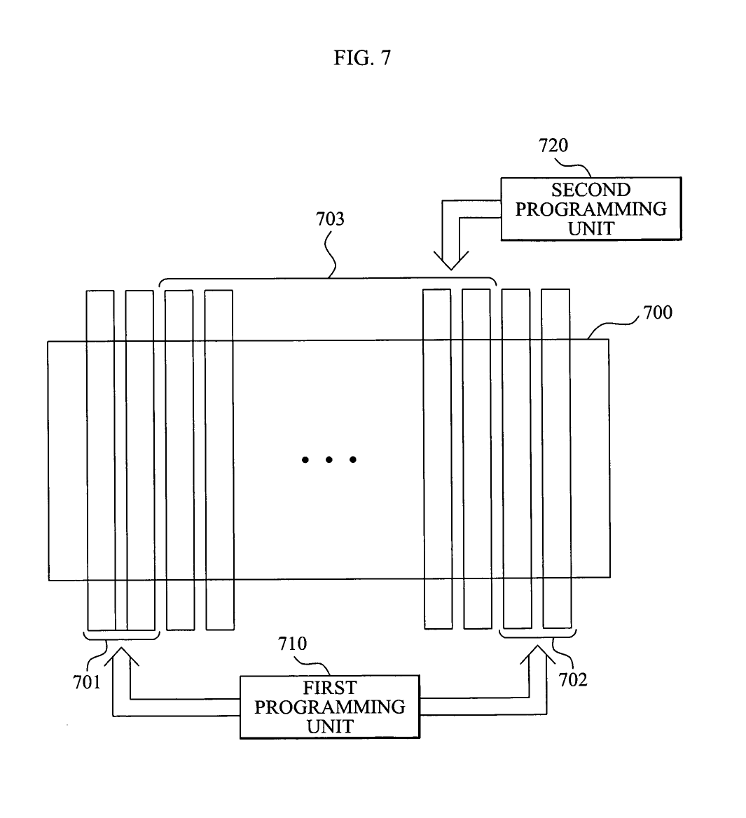

FIG. 7 illustrates a process of storing, by a multi-bit programming apparatus, data in a memory cell array 700 according to still another example embodiment.

Referring to FIG. 7, a first programming unit 710 of the multi-bit programming apparatus may store data corresponding to a number of first bits in memory cells that are connected to bit lines 701 and 702. The bit lines 701 and 702 may be located at outermost boundaries of the memory cell array 700.

A second programming unit 720 of the multi-bit programming apparatus may store data corresponding to a number of second bits in memory cells that are connected to bit lines 703. The bit lines 703 may be located in a central portion of the memory cell array 700.

Characteristics of memory cells of the memory cell array 700, manufactured through a semiconductor fabrication process, may be affected by a location of the memory cells in the memory cell array 700.

Since the memory cells located in the central portion of the memory cell array 700 may be surrounded by memory cells having similar characteristics, the memory cells may have consistent characteristics.

Conversely, since the memory cells located at the outermost boundaries of the memory cell array 700 may be in an environment where a surrounding topology may radically change, the memory cells may have unstable characteristics.

Accordingly, the multi-bit programming apparatus may set the number of first bits to be less than the number of second bits.

For example, when the number of first bits is two and the number of second bits is four, the first programming unit 710 may store two-bit data in each of the memory cells connected to the bit lines 701 and 702 located at the outermost boundaries of the memory cell array 700. The second programming unit 720 may store four-bit data in each of the memory cells connected to the bit lines 703.

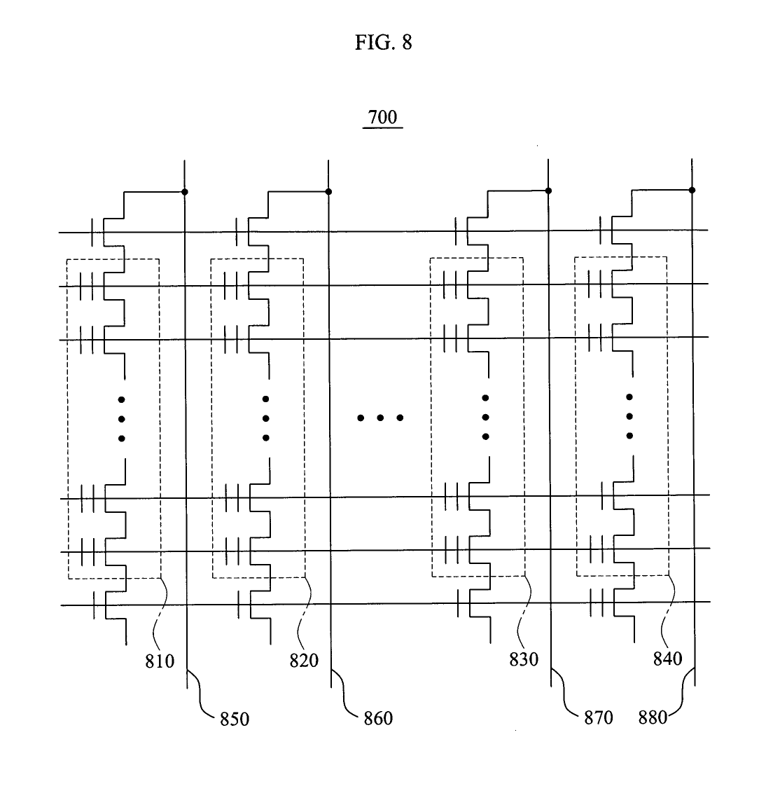

FIG. 8 illustrates a part of the memory cell array 700 in which data is stored by the multi-bit programming apparatus.

Referring to FIG. 8, memory cells 810 are connected in series with a bit line 850, memory cells 820 are connected in series with a bit line 860, memory cells 830 are connected in series with a bit line 870, and memory cells 840 are connected in series with a bit line 880.

The multi-bit programming apparatus may set one data storage density with respect to the memory cells 810 that are connected in series with one bit line 850.

Similarly, the multi-bit programming apparatus may set one data storage density with respect to the memory cells 820 that are connected in series with one bit line 860.

The memory cell array 700 configured as shown in FIG. 8 may be referred to as a NAND type flash memory. The NAND type flash memory may have a data access speed slower than a NOR type flash memory, but may increase the integration of memory cells. Accordingly, the NAND type flash memory may be advantageous for reducing costs.

The bit line 850 and remaining memory cells of the memory cells 810 may have to be accessed to access one of the memory cells 810.

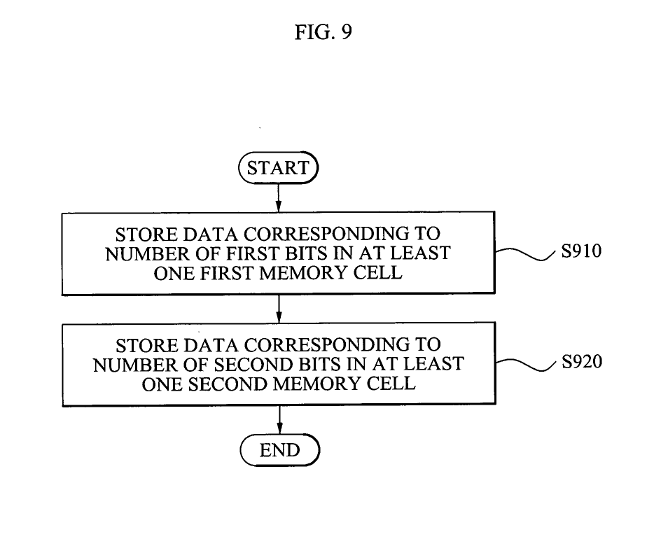

FIG. 9 is a flowchart illustrating a multi-bit programming method according to an example embodiment.

Referring to FIG. 9, in operation S910, the multi-bit programming method may store data corresponding to a number of first bits in at least one first memory cell that is connected to at least one first bit line.

In operation S920, the multi-bit programming method may store data corresponding to a number of second bits in at least one second memory cell that is connected to at least one second bit line.

In example embodiments, the at least one first memory cell may be connected to the at least one first bit line.

In example embodiments, the at least one second memory cell may be connected to the at least one second bit line.

According to example embodiments, the at last one first bit line may be an even bit line of a memory cell array, and the at least one second bit line may be an odd bit line of the memory cell array.

According to example embodiments, the at least one first bit line may correspond to a low address, and the at least one second bit line may correspond to a high address.

According to example embodiments, the at least one first bit line may be located at an outermost boundary of the memory cell array, and the at least one second bit line may correspond to a central portion of the memory cell array.

According to example embodiments, the multi-bit programming method may set the number of first bits to be different from the number of second bits.

In operation S910, the multi-bit programming method may store data corresponding to the number of first bits in the at least one first memory cell by changing a threshold voltage of the at least one first memory cell.

In operation S910, the multi-bit programming method may store data corresponding to the number of first bits in the at least one first memory cell by changing the threshold voltage of the at least one first memory cell to be any one of voltage levels corresponding to the number of first bits.

When the number of first bits is m, the multi-bit programming method may change the threshold voltage of the at least one first memory cell to be any one of 2m voltage levels in operation S910.

Data stored in the at least one first memory cell may be determined based on which threshold voltage of the at least one first memory cell is among 2m voltage levels.

In operation S920, the multi-bit programming method may store data corresponding to the number of second bits in the at least one second memory cell by changing a threshold voltage of the at least one second memory cell.

In operation S920, the multi-bit programming method may store data corresponding to the number of second bits in the at least one second memory cell by changing the threshold voltage of the at least one second memory cell to be any one of voltage levels corresponding to the number of second bits.

According to example embodiments, operations S910 and S920 may be simultaneously performed. To simultaneously perform operations S910 and S920, it may be necessary to control the performing of operations S910 and S920.

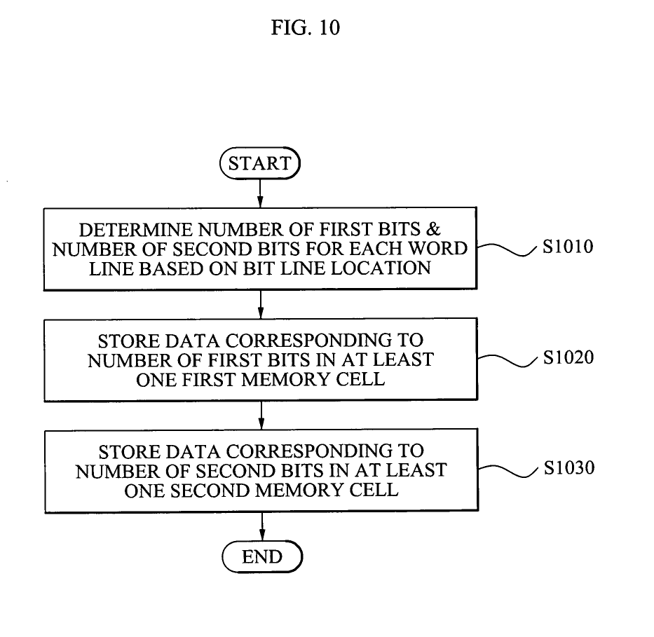

FIG. 10 is a flowchart illustrating a multi-bit programming method according to another example embodiment.

Referring to FIG. 10, in operation S1010, the multi-bit programming method may determine a number of first bits and a number of second bits for each word line based on a bit line location.

In operation S1020, the multi-bit programming method may store data corresponding to a number of first bits in at least one first memory cell that is connected to at least one first bit line.

In operation S1030, the multi-bit programming method may store data corresponding to a number of second bits in at least one second memory cell that is connected to at least one second bit line.

The number of first bits may be the data storage density of the at least one first memory cell that is connected to the at least one first bit line, and the number of second bits may be the data storage density of the at least one second memory cell that is connected to the at least one second bit line. The multi-bit programming method may set the data storage density of the first memory cell to be different from that of the second memory cell based on the bit line and the word line.

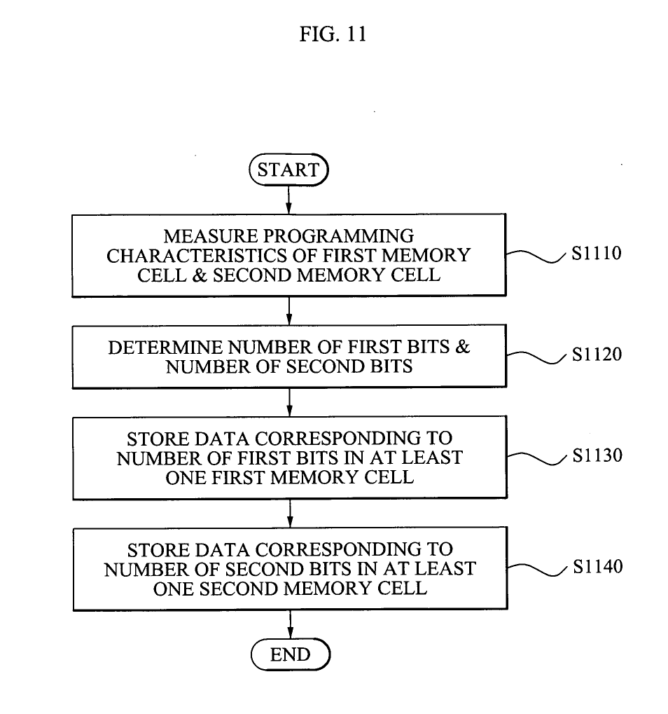

FIG. 11 is a flowchart illustrating a multi-bit programming method according to still another example embodiment.

Referring to FIG. 11, in operation S1110, the multi-bit programming method may measure programming characteristics of at least one first memory cell and at least one second memory cell.

In operation S120, the multi-bit programming method may determine a number of first bits and a number of second bits based on the measured programming characteristics.

In operation S1130, the multi-bit programming method may store data corresponding to the number of first bits in the at least one first memory cell that is connected to at least one first bit line.

In operation S1140, the multi-bit programming method may store data corresponding to the number of second bits in the at least one second memory cell that is connected to at least one second bit line.

The programming characteristics measured by the multi-bit programming method may be a changing tendency in a threshold voltage of the at least one first memory cell and the at least one second memory cell.

The multi-bit programming method according to example embodiments may be recorded in computer-readable media including program instructions to implement various operations embodied by a computer. The media may also include, alone or in combination with the program instructions, data files, data structures, and the like. The media and program instructions may be those specially designed and constructed for the purposes of example embodiments, or they may be of the kind well-known and available to those having skill in the computer software arts. Examples of computer-readable media may include magnetic media such as hard disks, floppy disks, and magnetic tape; optical media such as CD ROM disks and DVD; magneto-optical media such as optical disks; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of example embodiments.

While example embodiments have been particularly shown and described, it will be understood by those of ordinary skill in the art that various changes in form and details may be made therein without departing from the spirit and scope of the example embodiments as defined by the following claims.

What is claimed is:

1. A multi-bit programming apparatus for storing data in a memory cell of a memory cell array, the apparatus comprising:
a first programming unit that stores data corresponding to a number of first bits in at least one first memory cell that is connected to at least one first bit line; and
a second programming unit that stores data corresponding to a number of second bits in at least one second memory cell that is connected to at least one second bit line.

2. The apparatus of claim 1, wherein the at least one first memory cell is a group of memory cells that are connected in series with the at least one first bit line, and
wherein the at least one second memory cell is a group of memory cells that are connected in series with the at least one second bit line.

3. The apparatus of claim 1, wherein the at least one first bit line and the at least one second bit line are contiguously located.

4. The apparatus of claim 1, wherein the at least one first bit line is an even bit line, and
wherein the at least one second bit line is an odd bit line.

5. The apparatus of claim 1, wherein the at least one first bit line corresponds to a low address, and
wherein the at least one second bit line corresponds to a high address.

6. The apparatus of claim 1, wherein the at least one first bit line is located at an outermost boundary of the memory cell array.

7. The apparatus of claim 1, wherein the number of second bits is different from the number of first bits.

8. The apparatus of claim 1, further comprising:
a data density determination unit that determines the number of first bits and the number of second bits for each word line based on a bit line location.

9. The apparatus of claim 1, further comprising:
a programming characteristic measurement unit that measures programming characteristics of the at least one first memory cell and the at least one second memory cell; and
a data density measurement unit that determines the number of first bits and the number of second bits based on the measured programming characteristics.

10. The apparatus of claim 9, wherein the programming characteristics include a tendency of a threshold voltage to change for each of the at least one first memory cell and the at least one second memory cell.

11. The apparatus of claim 1, wherein the first programming unit stores data corresponding to the number of first bits in the at least one first memory cell by changing a threshold voltage of the at least one first memory cell, and
wherein the second programming unit stores data corresponding to the number of second bits in the at least one second memory cell by changing a threshold voltage of the at least one second memory cell.

12. The apparatus of claim 11, wherein the first programming unit stores data corresponding to the number of first bits in the at least one first memory cell by changing the threshold voltage of the at least one first memory cell to be any one of voltage levels corresponding to the number of first bits, and
wherein the second programming unit stores data corresponding to the number of second bits in the at least one second memory cell by changing the threshold voltage of the at least one second memory cell to be any one of voltage levels corresponding to the number of second bits.

13. The apparatus of claim 1, wherein the second programming unit stores the data corresponding to the number of second bits in the at least one second memory cell after the first programming unit stores the data corresponding to the number of first bits in the at least one first memory cell.

14. A multi-bit programming apparatus comprising:
a memory cell array; and
a programming control unit that stores data corresponding to a number of first bits in at least one first memory cell that is connected to at least one first bit line, and stores data corresponding to a number of second bits in at least one second memory cell that is connected to at least one second bit line.

15. A programming method of storing data in a memory cell of a memory cell array, the method comprising:
storing data corresponding to a number of first bits in at least one first memory cell that is connected to at least one first bit line; and
storing data corresponding to a number of second bits in at least one second memory cell that is connected to at least one second bit line.

16. The method of claim 15, wherein the at least one first memory cell is a group of memory cells that are connected in series with the at least one first bit line, and
wherein the at least one second memory cell is a group of memory cells that are connected in series with the at least one second bit line.

17. The method of claim 15, wherein the at least one first bit line is an even bit line, and
wherein the at least one second bit line is an odd bit line.

18. The method of claim 15, wherein the at least one first bit line corresponds to a low address, and
wherein the at least one second bit line corresponds to a high address.

19. The method of claim 15, wherein the at least one first bit line is located at an outermost boundary of the memory cell array.

20. The method of claim 15, wherein the number of second bits is different from the number of first bits.

21. The method of claim 15, further comprising:
determining the number of first bits and the number of second bits for each word line based on a bit line location.

22. The method of claim 15, further comprising:
measuring programming characteristics of the at least one first memory cell and the at least one second memory cell; and
determining the number of first bits and the number of second bits based on the measured programming characteristics.

23. The method of claim 22, wherein the programming characteristics include a tendency of a threshold voltage to change for each of the at least one first memory cell and the at least one second memory cell.

24. A computer-readable recording medium storing a program for implementing a programming method of storing data in a memory cell of a memory cell array, the method including:
storing data corresponding to a number of first bits in at least one first memory cell that is connected to at least one first bit line; and
storing data corresponding to a number of second bits in at least one second memory cell that is connected to at least one second bit line.
